(19) United States
(12) Patent Application Publication
(10) Pub. No.: US 2023/0244834 A1
(43) Pub. Date: Aug. 3, 2023

(54) SYSTEMS AND METHODS FOR CARGO OPTIMIZATION BASED ON DRIVER BEHAVIOR AND VEHICLE DYNAMICS

(71) Applicant: TOYOTA RESEARCH INSTITUTE, INC., LOS ALTOS, CA (US)

(72) Inventor: HA-KYUNG KWON, Los Altos, CA (US)

(21) Appl. No.: 17/588,632

(22) Filed: Jan. 31, 2022

(51) Int. Cl. G06F 30/27

(52) U.S. Cl. CPC G06F 30/27; B60Q 9/00

(57) ABSTRACT

Systems and methods for optimizing the storage of cargo/use of cargo space or area(s) are provided. A recommendation system can optimize cargo storage in a vehicle by taking into consideration, the characteristics of the cargo itself, as well as driver behavior associated with the vehicle, vehicle characteristics, and vehicle operating dynamics. Based on these considerations, recommendations for optimized packing/storage of the cargo can be provided to a user.

### TECHNICAL FIELD

The present disclosure relates generally to optimizing use of a vehicle's cargo space, and more particularly to determining optimal use of a vehicle's cargo space based on considerations involving driver behavior and vehicle operating dynamics.

### DESCRIPTION OF RELATED ART

Vehicles such as sedans may have a cargo area in the form of an enclosed trunk at the rear of the vehicle. Vehicles such as sport utility vehicles (SUVs) may have a cargo area that is not separated from the rest of the vehicle interior, but rather divided therefrom by virtue of seats/seat mode (“up” in seating position or “down” in cargo position). Vehicles such as trucks have still another type of cargo area in the form of an open truck bed. Other vehicles, may have various cargo areas throughout the interior of the vehicle (e.g., cubbies, glove compartments, etc.) or in other areas external to the vehicle's internal space. For example, rear-engine vehicles may have a cargo area located under the front hood.

Cargo areas are used to store objects for later use, hold/support objects during transport, and so on. Cargo areas can be configurable. For example, the cargo area of an SUV may comprise a cargo area having some first cargo capacity when the rear seats of the SUV are in the up/seating position or mode. That same cargo area can be expanded to comprise some second cargo capacity when the rear seat(s) of the SUV are in the down/cargo mode.

### BRIEF SUMMARY OF THE DISCLOSURE

In accordance with some embodiments, a system may comprise a processor, and a memory unit operatively connected to the processor and including instructions that when executed cause the processor to: simulate movement of a vehicle in accordance with a driving scenario and generate a first model representative of the simulated movement of the vehicle; generate a second model representative of movement of an item to predict how the item will move in response to the simulated movement of the vehicle, wherein input to the second model represents physical characteristics of the item; combine the first and second models to determine predicted movement of the item in one or more areas of the vehicle in response to the simulated movement of the vehicle; perform a recommendation simulation to determined recommended placement of the item in the one or more areas of the vehicle; and

output a notification reflecting the determined recommended placement of the item in the one or more areas of the vehicle.

In some embodiments, the memory unit includes instructions that when executed further cause the processor to determine an experienced change in displacement or change in momentum at the one or more areas of the vehicle in response to the simulated movement of the vehicle.

In some embodiments, the instructions that when executed cause the processor to combine the first and second models further cause the processor to determine predicted movement of the item at the one or more areas of the vehicle.

In some embodiments, the instructions that when executed cause the processor to combine the first and second models further cause the processor to generate a sequentially combined model.

In some embodiments, the instructions that when executed cause the processor to generate a sequentially combined model further cause the processor to use the output of the first model as an input to the second model, and executing the second model.

In some embodiments, the instructions that when executed cause the processor to generate a parallel combined model.

In some embodiments, the instructions that when executed cause the processor to generate a parallel combined model further cause the processor to execute the first and second models in parallel until convergence with the first and second models is achieved.

In some embodiments, the instructions that when executed cause the processor to perform the recommendation simulation comprises negating predicted movement of the item at the one or more areas of the vehicle that are undesirable.

In some embodiments, the memory unit includes further instructions that when executed cause the processor to determine predicted item interactions based on item-related interaction information input into the combination of the first and second models at the one or more areas of the vehicle.

In accordance with some embodiments, a system may comprise a processor, and a memory unit operatively connected to the processor and including instructions that when executed cause the processor to: predict movement of an item in response to a plurality of external forces applied to the item, the plurality of external forces comprising movement of a vehicle in which the item is stored; predict movement of the vehicle in response to a plurality of driving scenarios; predict the movement of the item in particular locations of the vehicle relative to each of the plurality of driving scenarios based on a prediction generated by one or more models incorporating the predicted movement of the item responsive to the plurality of external forces and the predicted movement of the vehicle responsive to the plurality of driving scenarios; and determine whether the movement of the item in each of the particular locations is commensurate with a desired storage location for the item; and upon determining that the movement of the item in one or more of the particular locations is commensurate with a desired storage location, output a recommendation regarding placement of the item in the vehicle in accordance with the desired storage location for the item.

In some embodiments, the movement of the item is predicted by a first machine learning model considering physical characteristics of the item.

In some embodiments, the movement of the vehicle is predicted by a second machine learning model considering at least one of driving characteristics of a user operating the vehicle, external conditions, and vehicle dynamics associated with the vehicle.

In some embodiments, the movement of the item in the particular locations of the vehicle is predicted by a combination of the first and second machine learning models.

In some embodiments, the combination of the first and second machine learning models comprises a sequentially combined machine learning model.

In some embodiments, the memory unit includes further instructions that when executed cause the processor to use the predicted movement of the item determined by the first machine learning model as input to the second machine learning model and executing the second machine learning model.

In some embodiments, the combination of the first and second machine learning models comprises a parallel combined machine learning model.

In some embodiments, the memory unit includes further instructions that when executed cause the processor to execute the first and second machine learning models until convergence is achieved.

In some embodiments, the memory unit includes further instructions that when executed cause the processor to determine predicted item interactions based on item-related interaction information input into the combination of the first and second machine learning models.

In some embodiments, the memory unit includes further instructions that when executed cause the processor determine one or more of the particular locations of the vehicle at which the predicted movement of the item is undesirable.

In some embodiments, the instructions that when executed cause the processor to output the recommendation regarding placement of the item further cause the processor to exclude the determined one or more of the particular locations of the vehicle at which the predicted movement of the item is undesirable.

### BRIEF DESCRIPTION OF THE DRAWINGS

The present disclosure, in accordance with one or more various embodiments, is described in detail with reference to the following figures. The figures are provided for purposes of illustration only and merely depict typical or example embodiments.

FIG. 1 is a schematic representation of an example vehicle with which embodiments of the systems and methods disclosed herein may be implemented.

FIG. 2A illustrates a perspective view of an example cargo area of a vehicle.

FIG. 2B illustrates a perspective view of other example cargo areas of a vehicle.

FIG. 3A is a schematic representation of an example cargo optimization system in accordance with one embodiment.

FIG. 3B is a schematic representation of an example calculation unit/recommendation engine of the cargo optimization system of FIG. 3A.

FIG. 4 is a flow chart illustrating example operations performed to generate a storage or item placement recommendation in accordance with one embodiment.

FIG. 5 is an example computing component that may be used to implement various features of embodiments described in the present disclosure.

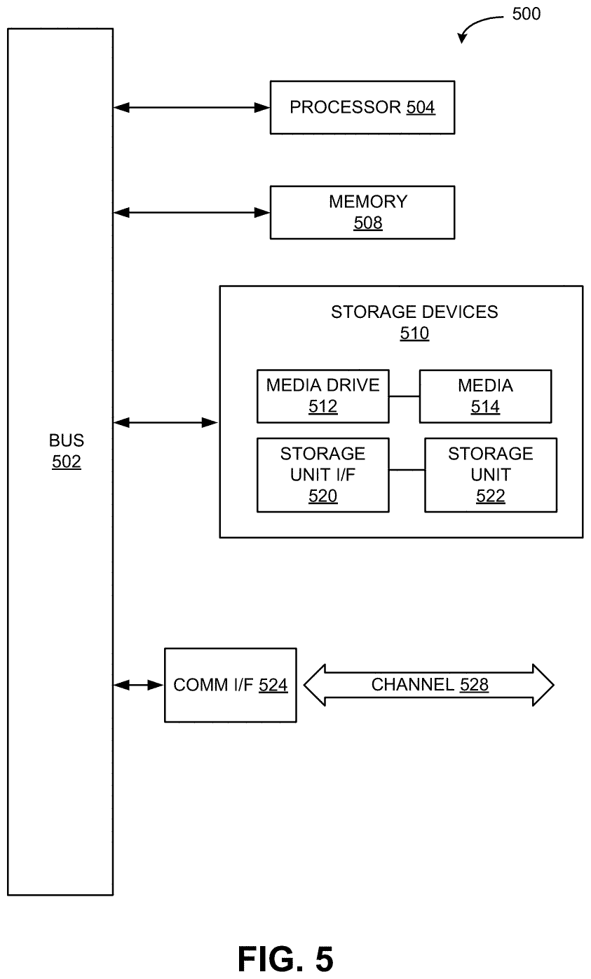

The figures are not exhaustive and do not limit the present disclosure to the precise form disclosed.

### DETAILED DESCRIPTION

As noted above, vehicles may have cargo areas that can be used to store/carry items or objects. When a vehicle is in use, the items or objects being stored/carried in a cargo area can be subject to moving. For example, during acceleration events (that can result in a vehicle lurching forward), objects in a cargo area may move or shift in the opposite direction. For example, during a braking event, objects contained in or by the cargo area can move or shift forward from an initial position. Still another example of shifting cargo (objects in the cargo area) is when a vehicle navigates a turn.

It should also be noted that vehicle passengers or operators may place cargo/objects on the seats of a vehicle, in a door cubby, or on some other surface or area of the vehicle. Currently, when packing or arranging items to be stored or transported in a vehicle, a person has no guidance on how to arrange those items in the vehicle's cargo space(s) or other areas, nor is a person made aware of potentially unsecure, or even dangerous, placement of an item(s). Conventional vehicles may provide certain cargo accessories such as cargo nets to mitigate shifting/movement of items. Conventional vehicles may also provide various partitions or “sub-areas” in a cargo area meant to hold/contain certain objects/types of objects, or to hold/contain items of a certain size(s), etc.

However, placement and orientation of an item(s) as well as use of cargo accessories is nevertheless left to the judgment of a user (vehicle operator, passenger, or other person(s) depositing items in a vehicle). It is not unusual for a person to select an inappropriate location for cargo. In some cases, a person may force cargo into a cargo area (or other area of the vehicle) that should not be used for cargo, or the cargo may not be properly secured. In still other instances, even if a person “properly” places/locates cargo, during vehicle use, as noted above, that cargo may move or shift.

Moreover, that movement or shifting can vary depending on vehicle operating dynamics. For example, placement of an item in a cargo area may be appropriate, e.g., safe, when the vehicle is being operated in a more controlled manner, e.g., non-excessive speeds, and with less aggressive vehicle maneuvering. However, if that same vehicle is operated in a more aggressive manner, what may have been an appropriate location for an item ceases to be appropriate, as the item can be more prone to moving or commensurately more aggressive shifting.

Accordingly, embodiments of the present disclosure are directed to cargo optimization, in particular, improvements rooted in computer technology for optimizing the storage of cargo/use of cargo space or area(s). In some embodiments, recommendations regarding the stowing or placement/orienting of cargo may be provided to a user or person packing or stowing cargo. Although embodiments disclosed herein may be related to optimizing cargo in a vehicular context, embodiments can be used or adapted for optimizing the storage of cargo in any context or environment.

In some embodiments, a recommendation system or engine can optimize cargo storage in a vehicle by taking into consideration, the characteristics of the cargo itself, e.g., size and shape, as well as driver behavior associated with the vehicle, vehicle characteristics, and vehicle operating dynamics. The driver behavior may be driver behavior monitored/sensed over some period of time or in real-time, while vehicle dynamics can be real-time vehicle operating dynamics, such as speed, yaw, roll, etc. Vehicle dynamics can also refer to 3^{rd}-party-provided vehicle dynamics data or information, e.g., from the vehicle manufacturer, as well as historical data reflecting vehicle operating dynamics relative to certain loads. Further still, vehicle dynamics data can be related to or based on road conditions, such as physical roadway characteristics (existence of potholes, for example), dynamic environmental considerations such as the weather, as well as traffic conditions, or other factors that may impact vehicle operating dynamics.

It should be noted that the terms “optimize,” “optimal” and the like as used herein can be used to mean making or achieving performance as effective or perfect as possible. However, as one of ordinary skill in the art reading this document will recognize, perfection cannot always be achieved. Accordingly, these terms can also encompass making or achieving performance as good or effective as possible or practical under the given circumstances, or making or achieving performance better than that which can be achieved with other settings or parameters.

In some embodiments, the provided recommendations can be output from the recommendation engine, which itself may comprise various subsystems. In some embodiments, the recommendation engine may comprise a driver behavior determination component, a vehicle dynamics determination component, a cargo characteristics component, and a prediction or recommendation component. It should be noted that more or less components or subsystems can make up the aforementioned recommendation engine.

In general, the word “component,” “engine,” “system,” “database,” data store,” and the like, as used herein, can refer to logic embodied in hardware or firmware, or to a collection of software instructions, possibly having entry and exit points, written in a programming language, such as, for example, Java, C or C++. A software component may be compiled and linked into an executable program, installed in a dynamic link library, or may be written in an interpreted programming language such as, for example, BASIC, Perl, or Python. It will be appreciated that software components may be callable from other components or from themselves, and/or may be invoked in response to detected events or interrupts. Software components configured for execution on computing devices may be provided on a computer readable medium, such as a compact disc, digital video disc, flash drive, magnetic disc, or any other tangible medium, or as a digital download (and may be originally stored in a compressed or installable format that requires installation, decompression or decryption prior to execution). Such software code may be stored, partially or fully, on a memory device of the executing computing device, for execution by the computing device. Software instructions may be embedded in firmware, such as an EPROM. It will be further appreciated that hardware components may be comprised of connected logic units, such as gates and flip-flops, and/or may be comprised of programmable units, such as programmable gate arrays or processors.

The systems and methods disclosed herein may be implemented with or by any of a number of different vehicles and vehicle types. For example, the systems and methods disclosed herein may be used with automobiles, trucks, motorcycles, recreational vehicles and other like on-or off-road vehicles. In addition, the principles disclosed herein may also extend to other vehicle types as well.

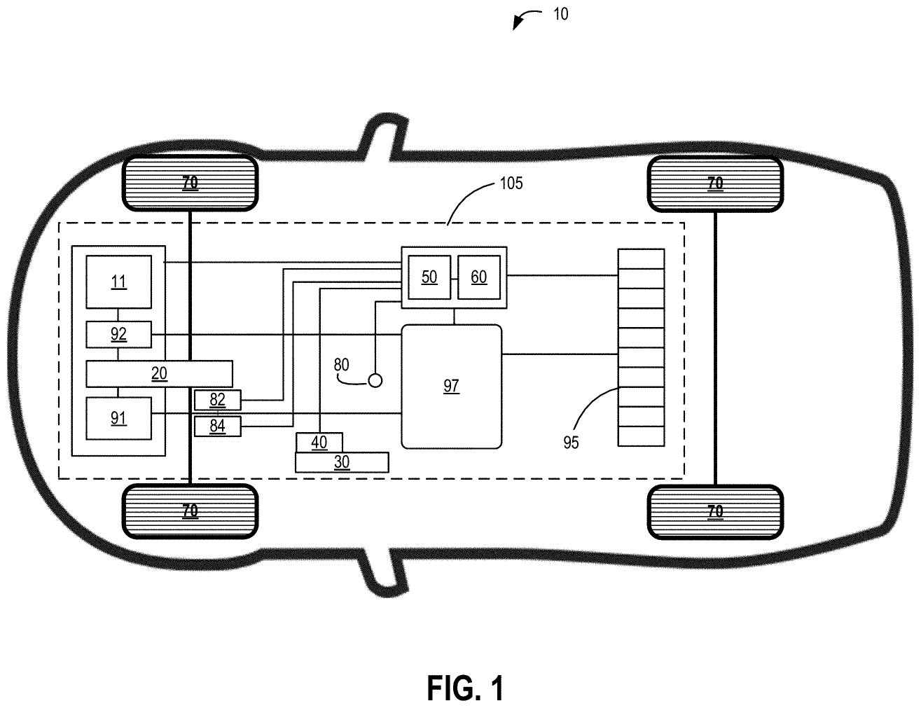

FIG. 1 illustrates an example vehicle 10 in which various embodiments for cargo optimization may be implemented. It should be understood that various embodiments disclosed herein may be applicable to/used in various vehicles (internal combustion engine (ICE) vehicles, fully electric vehicles (EVs), etc.) that are fully or partially autonomously controlled/operated, and as noted above, even in non-vehicular contexts, such as, e.g., shipping container packing.

Vehicle 10 can include drive force unit 5 and wheels 70. Drive force unit 5 may include an engine 11, motor generators (MGs) 91 and 92, a battery 95, an inverter 97, a brake pedal 30, a brake pedal sensor 40, a transmission 20, a memory 60, an electronic control unit (ECU) 50, a shifter 80, a speed sensor 82, and an accelerometer 84.

Engine 10 primarily drives the wheels 70. Engine 10 can be an ICE that combusts fuel, such as gasoline, ethanol, diesel, biofuel, or other types of fuels which are suitable for combustion. The torque output by engine 11 is received by the transmission 20. MGs 91 and 92 can also output torque to the transmission 20. Engine 10 and MGs 91 and 92 may be coupled through a planetary gear (not shown in FIG. 1B). The transmission 20 delivers an applied torque to the wheels 70. The torque output by engine 11 does not directly translate into the applied torque to the wheels 70.

MGs 91 and 92 can serve as motors which output torque in a drive mode, and can serve as generators to recharge the battery 95 in a regeneration mode. The electric power delivered from or to MGs 91 and 92 passes through inverter 97 to battery 95. Brake pedal sensor 40 can detect pressure applied to brake pedal 30, which may further affect the applied torque to wheels 70. Speed sensor 82 is connected to an output shaft of transmission 20 to detect a speed input which is converted into a vehicle speed by ECU 50. Accelerometer 84 is connected to the body of vehicle 10 to detect the actual deceleration of vehicle 10, which corresponds to a deceleration torque.

Transmission 20 is a transmission suitable for any vehicle. For example, transmission 20 can be an electronically controlled continuously variable transmission (ECVT), which is coupled to engine 11 as well as to MGs 91 and 92. Transmission 20 can deliver torque output from a combination of engine 11 and MGs 91 and 92. The ECU 50 controls the transmission 20, utilizing data stored in memory 60 to determine the applied torque delivered to the wheels 70. For example, ECU 50 may determine that at a certain vehicle speed, engine 11 should provide a fraction of the applied torque to the wheels while MG 91 provides most of the applied torque. ECU 50 and transmission 20 can control an engine speed (N_{E}) of engine 11 independently of the vehicle speed (V).

ECU 50 may include circuitry to control the above aspects of vehicle operation. ECU 50 may include, for example, a microcomputer that includes a one or more processing units (e.g., microprocessors), memory storage (e.g., RAM, ROM, etc.), and I/O devices. ECU 50 may execute instructions stored in memory to control one or more electrical systems or subsystems in the vehicle. ECU 50 can include a plurality of electronic control units such as, for example, an electronic engine control module, a powertrain control module, a transmission control module, a suspension control module, a body control module, and so on. As a further example, electronic control units can be included to control systems and functions such as doors and door locking, lighting, human-machine interfaces, cruise control, telematics, braking systems (e.g., anti-lock braking system (ABS) or electronic stability control (ESC)), battery management systems, and so on. These various control units can be implemented using two or more separate electronic control units, or using a single electronic control unit.

MGs 91 and 92 each may be a permanent magnet type synchronous motor including for example, a rotor with a permanent magnet embedded therein. MGs 91 and 92 may each be driven by an inverter controlled by a control signal from ECU 50 so as to convert direct current (DC) power from battery 95 to alternating current (AC) power, and supply the AC power to MGs 91, 92. MG 92 may be driven by electric power generated by motor generator MG91. It should be understood that in embodiments where MG91 and MG92 are DC motors, no inverter is required. The inverter, in conjunction with a converter assembly may also accept power from one or more of MGs 91, 92 (e.g., during engine charging), convert this power from AC back to DC, and use this power to charge battery 95 (hence the name, motor generator). ECU 50 may control the inverter, adjust driving current supplied to MG 92, and adjust the current received from MG91 during regenerative coasting and braking.

Battery 95 may be implemented as one or more batteries or other power storage devices including, for example, lead-acid batteries, lithium ion, and nickel batteries, capacitive storage devices, and so on. Battery 95 may also be charged by one or more of MGs 91, 92, such as, for example, by regenerative braking or by coasting during which one or more of MGs 91, 92 operates as generator. Alternatively (or additionally, battery 95 can be charged by MG 91, for example, when vehicle 10 is in idle (not moving/not in drive). Further still, battery 95 may be charged by a battery charger (not shown) that receives energy from engine 11. The battery charger may be switched or otherwise controlled to engage/disengage it with battery 95. For example, an alternator or generator may be coupled directly or indirectly to a drive shaft of engine 11 to generate an electrical current as a result of the operation of engine 11. Still other embodiments contemplate the use of one or more additional motor generators to power the rear wheels of a vehicle (e.g., in vehicles equipped with 4-Wheel Drive), or using two rear motor generators, each powering a rear wheel.

Battery 95 may also be used to power other electrical or electronic systems in the vehicle. Battery 95 can include, for example, one or more batteries, capacitive storage units, or other storage reservoirs suitable for storing electrical energy that can be used to power MG 91 and/or MG 92. When battery 95 is implemented using one or more batteries, the batteries can include, for example, nickel metal hydride batteries, lithium ion batteries, lead acid batteries, nickel cadmium batteries, lithium ion polymer batteries, and other types of batteries.

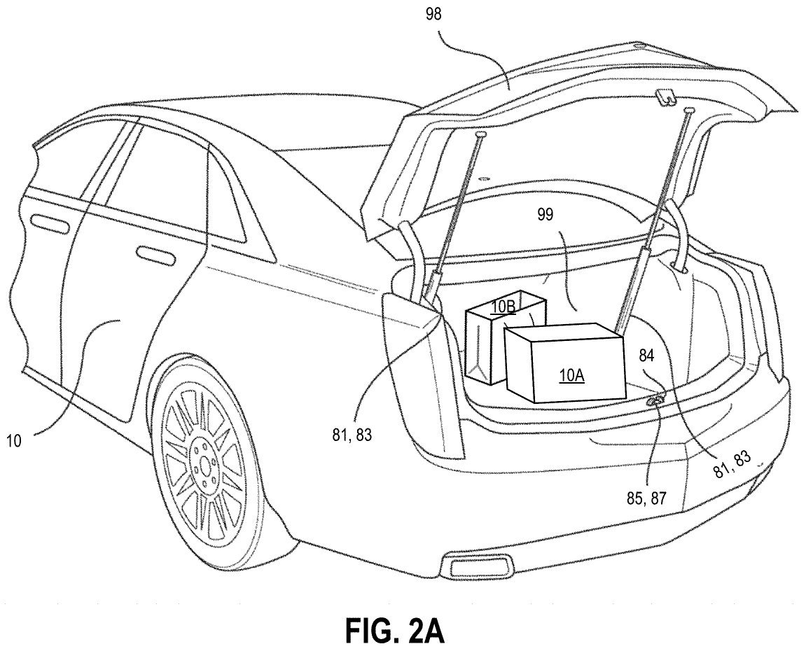

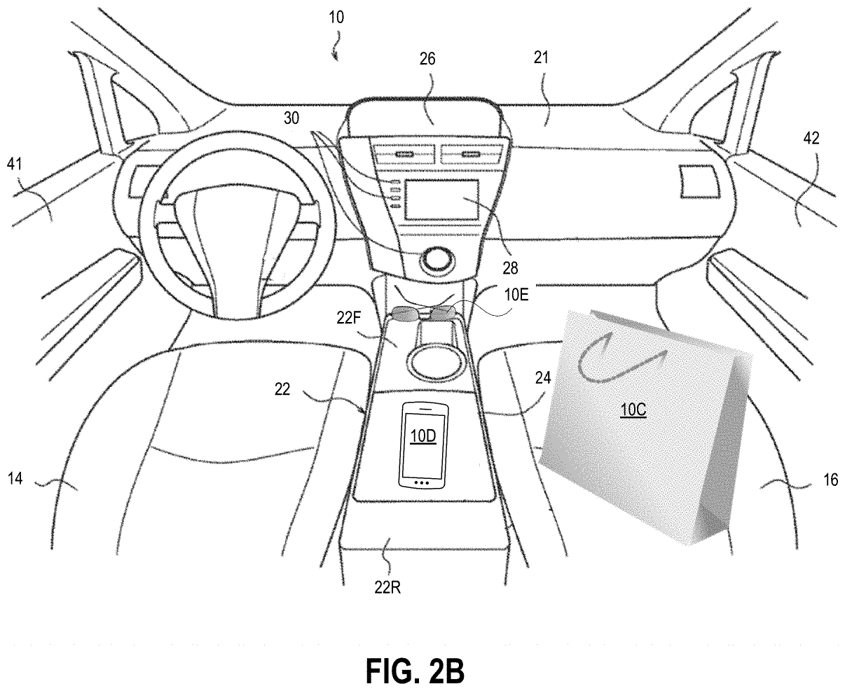

FIG. 2A is a schematic perspective rear view of one example of the vehicle 10 showing a cargo area in the form of a vehicle trunk 99 and a cargo area door 98 in the form of a trunk lid. The vehicle 10 is provided with cargo area door opening and closing mechanisms 81/83 in the form of one or more hydraulic cylinders which are operable to perform both the door opening and closing functions. Vehicle 10 may employ other types of opening and closing mechanisms. Vehicle 10 is also provided with locking and unlocking mechanisms 84/85/87 to lock and unlock the cargo area door 98 when the cargo area door 98 is in a closed configuration.

As illustrated in FIG. 2A, vehicle trunk 99 contains therein, two items/pieces of cargo, i.e., a box 10A and a bag 10B. It should be understood that the illustrated cargo is an example of how vehicle trunk 99 may be used to stow or store certain items. As can be appreciated, were vehicle 10 to move with enough speed, box 10A and bag 10B would likely move/shift position or orientation within vehicle trunk 99. If one or both items were heavy enough, their movement could create noise that may distract the operator of vehicle 10, damage the interior of vehicle trunk 99, etc. Moreover, the contents of bag 10B might spill over into vehicle trunk 99, or box 10A may crush or deform the bag 10B or its contents.

FIG. 2B illustrates an interior cabin of vehicle 10. As illustrated in FIG. 2B, the cabin of vehicle 10, bounded in part, e.g., by driver and passenger doors 41 and 42, respectively, may include a driver's seat 14, a front passenger's seat 16 and a rear seat (not shown). A dash/dashboard 21 may be disposed in front of the driver's seat 14 and the front passenger's seat 16. A center console 22 may be disposed between the driver's seat 14 and the front passenger's seat 16. A console box may be provided at the rear portion of the center console 22, 22R. The front end portion of the center console 22, 22F, may be integrally connected to a portion of the instrument pane 261 at/underneath head unit 28 with infotainment controls 30.

As illustrated in FIG. 2B, various areas of the interior cabin of vehicle 10 may be used by a driver, for example, to place cargo. A smartphone 10D is illustrated as being disposed atop a center console 22. Glasses 10E may be disposed in a semi-enclosed space of the front portion 22F of center console 22. A bag 10C may be disposed atop passenger seat 16. Any one or more of bag 10C, smartphone 10D, or glasses 10E may move or shift or become re-oriented in response to vehicle operating/operational characteristics, such as acceleration events, braking events, turning events, forward/backward motion of vehicle 10, etc. It should be understood that the movement/re-positioning/re-orienting (or the amount thereof) of one or more of these items 10C-10E may depend on the physical characteristics of each item (shape, size, weight, etc.) relative to each other, the surface/area on or in which items 10C-10E have been disposed, or movement of vehicle 10.

For example, smartphone 10D may remain on the surface of center console 22 due to the respective surfaces of center console 22 and smartphone 10D being relatively flat and touching, during “smooth” vehicle operation. However, in response to more aggressive driving operation(s), the friction between smartphone 10D and the surface of center console 22 may not be sufficient to prevent smartphone 10D from slipping/moving. For example, bag 10C may, despite its shape not conforming to a surface of seat 16, nevertheless remain on seat 16 due to various bolstered areas or raised areas/lips of seat 16 preventing “major” movement of bag 10C. That is, bag 10C may slip or slide to some extent on seat 16, but may not slide or slip completely off seat 16. It should be understood that aspects of various embodiments of the present disclosure related to the movement of cargo may be relative and dependent on a variety of factors. For example, in some embodiments, movement of a relatively lighter weight object, such as glasses 10E may be allowed more movement or displacement inasmuch as the movement of glasses 10E typically would not prevent a safety hazard (as opposed to a heavier object or object with pointed/sharp areas).

In one or more arrangements, one or more of the components described herein can include artificial or computational intelligence elements, e.g., neural network, fuzzy logic or other machine learning algorithms. Further, in one or more arrangements, one or more of the components can be distributed among a plurality of the components described herein. In one or more arrangements, two or more of the components described herein can be combined into a single component.

Although specific components will be described herein, it is understood that additional controls, systems and/or modules may be included if needed to perform the functions described herein, depending on the design of a particular vehicle. Vehicle embodiments described herein are assumed to include sufficient systems and/or elements to autonomously execute all of the commands needed to perform the various cargo optimization operations disclosed herein.

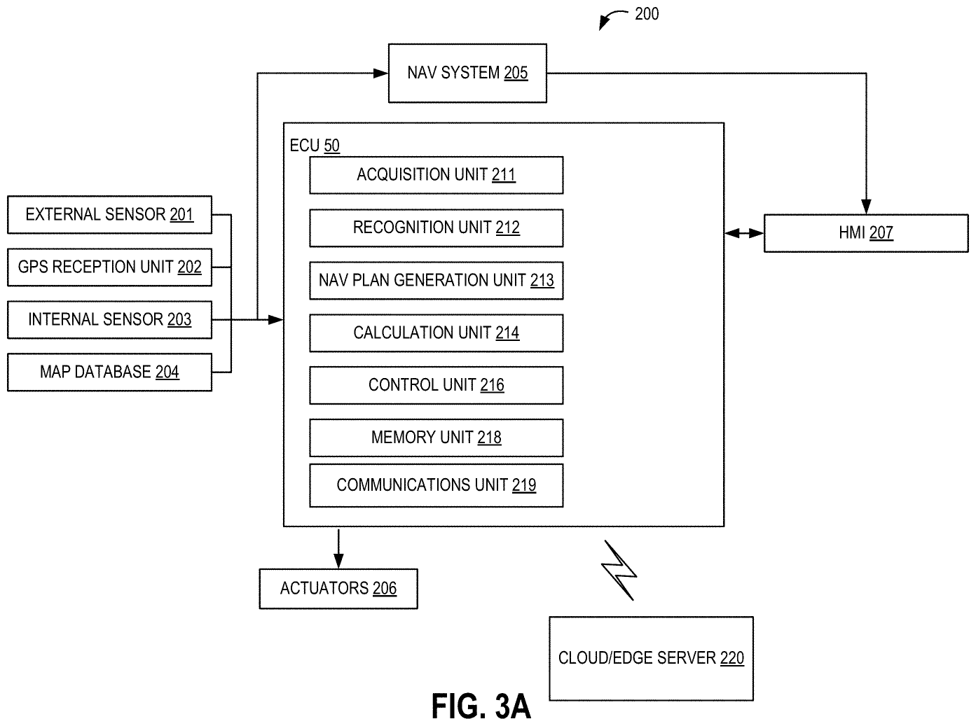

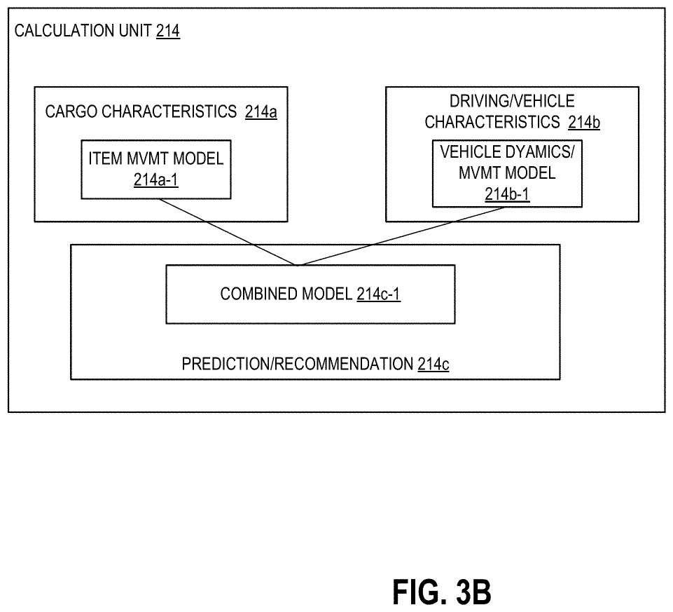

FIG. 3A illustrates an example cargo optimization system 200 that may be used to determine optimal position/location/orientation of cargo in a particular space, such as a cargo area within a vehicle, e.g., vehicle 10. In some embodiments, cargo optimization system 200 may be used to determine optimal position/location/orientation of cargo for more generalized/non-specific cargo areas. For example, driving dynamics, cargo item or vehicle characteristics, and such factors may be used to determine, generally, where best to place/how best to orient the cargo item regardless of cargo area/vehicle. That is, cargo optimization system 200 may determine and provide recommendations for the placement of certain cargo items in some area(s) of any vehicle. A vehicle fleet rental organization may use cargo optimization system 200 to determine and provide cargo stowing recommendations for all sedans, all SUVs, etc., (i.e., type of vehicle) rather than a particular vehicle.

Cargo optimization system 200 may be installed in vehicle 10, and executes cargo optimization operations of vehicle 10. As described herein, cargo optimization can include determining relevant characteristics of cargo to be stowed, e.g., shape, size or footprint, weight/mass, etc., where relevance of characteristics may depend on whether or not a particular characteristics impacts or affects its storage/placement as an item of cargo.

The volume of an item may be determined by data entry by a person or by estimations by taking a picture of a cargo item(s) to be transported. Weight may be determined by data entry or by estimations based on a picture of the cargo item. For example, if the item to be transported is a grocery bag, the system may utilize an estimated weight based on historical data or other information. Volume or weight data may also be determined if the cargo item includes identifying information, such as a barcode, that would allow the system to retrieve volume/weight information from an external/3^{rd} party database.

The recommendation system can also determine the fragility of the item. Regarding fragility, the information could be binary (breakable/not breakable) or could be a variable indicating how breakable something is. For example, an unboxed tea set may receive a 1.0 score, a wooden baseball bat may receive a 0.0 score, and a boxed (packaged within a protective container) tea set may receive a 0.5 score, etc. A database may be able to cross-reference a particular item with one or more scores. Additionally or alternatively, the driver of the vehicle may be able to classify the item as breakable/unbreakable/possibly breakable. In this or other aspects of embodiments described herein, certain weights/weighting can be employed to further categorize or classify cargo items, as well as operating characteristics of a vehicle. For example, if a cargo item is exceedingly heavy relative to it's size, e.g., is dense enough to surpass a given threshold, the weight of the cargo item may be a more impactful consideration as opposed to the shape of the cargo item. Accordingly, the weight of the cargo item can be “weighted” more heavily, e.g., given greater priority in terms of a factor to be considered when determining optimal placement/orientation of the cargo item.

Cargo optimization may further comprise determining relevant characteristics of the vehicle and its operation, where relevance may depend on whether or not the physical characteristic(s) of a vehicle (such as interior stowage space size and shape(s), surface material(s) of the cargo area(s)), as well as driving dynamics associated with the vehicle. It should noted that driving dynamics can be information specific to the vehicle itself, e.g., the type of suspension the vehicle chassis relies on to provide its characteristic ride quality, the amount of roll, yaw, pitch, etc. the vehicle may experience during various driving conditions/operations. In some embodiments, such driving dynamics may be gleaned from/based on the driver of the vehicle (current, historical, or both), or some aggregation of information regarding typical or historical use of the vehicle. Driving dynamics may also include the resulting impact of the environment on operation of the vehicle, e.g., road conditions due to weather events, road conditions due to road surface features, etc.

It should be understood that vehicle dynamics may be measured or determined in a number of different ways. In one example, the vehicle dynamics may be a set of properties provided by another party regarding the operation of the vehicle. For example, the vehicle manufacturer may be able to provide detailed models regarding how the vehicle acts in different situations. Additionally or alternatively, the vehicle dynamics may be calculated by monitoring forces measured by one or more sensors, such as longitudinal or lateral sensors (embodiments of sensors discussed herein) that can determine one or more dynamics of the vehicle. Further still, the vehicle dynamics may be determined using the combination of models provided by another party with measurements regarding how the vehicle reacts. For example, the vehicle dynamics may be determined by utilizing information regarding the center of gravity from a manufacturer in combination with the vehicle's movement (or sway) as the vehicle is operated. In some embodiments, cargo optimization system 200 may modify the vehicle dynamics of the vehicle to consider the mass or other physical dimensions of the cargo item(s) when added to the vehicle. In some embodiments, cargo optimization system 200 may also consider surface-specific dynamics. For example, if an item is placed on the seat, the seat may provide additional shock-absorbing properties that the system may consider. Further still, the system may also consider frictional aspects of one or more vehicle surfaces when considering vehicle dynamics. For example, the vehicle's seat may be made of leather and have a low coefficient of friction, while the trunk of the vehicle may be rubberized and therefore have a much higher frictional coefficient. In still other embodiments, cargo optimization system 200 may modify the vehicle dynamics based on weather.

Considering such factors, one or more appropriate or optimal locations/orientations of cargo may be determined, where appropriateness or optimality may be dependent upon safe operation of the vehicle, safety of vehicle passengers, damage to the cargo items as well as to the vehicle. Regarding determining the appropriate location/position of an item, cargo optimization system 200 (as alluded to above) will consider the behavior of the driver, the vehicle dynamics of the vehicle transporting the item, and the physical properties of the vehicles. In some embodiments, the goal of cargo optimization system 200 is to suggest where particular items should be located within vehicle 200 such that they arrive undamaged, or that the vehicle 200 and its passengers arrive unharmed/undamaged. In some cases, cargo optimization system 200 may recommend multiple locations for a cargo item to be stowed. In other cases, cargo optimization system 200 may only recommend one or two safe locations for the item. Additionally, if it is determined that the driver behavior, vehicle dynamics, and physical properties of the items are such that they are unlikely to be safely transported under the situations, cargo optimization system 200 may indicate that the item is unlikely to make it to the destination undamaged.

Determining appropriate or optical location/placement of a cargo item can also be learned. For example, cargo optimization system 200, using one or more cameras that can monitor items located within the vehicle, may observe the movement of objects based on its recommendations and may modify its decision-making process based on those observations. Determining the appropriate location/orientation may also determine the driver's behavior on a specific route. For example, if the driver tends to operate vehicle 10 aggressively on the highway, but more cautiously on side streets, cargo optimization system 200 will consider these factors when determining the appropriate location for storing an item of cargo.

Determining an appropriate location for an item of cargo to be stored may also comprise considering how different objects interact with each other. For example, placing a bowling ball on the backseat floor of the vehicle may be appropriate in some situations. Similarly, placing a cake on the backseat floor of the vehicle may also be appropriate in other situations. However, placing both items on the backseat floor at the same time would be inappropriate as it is likely that the bowling bowl would roll into/over the cake, destroying or otherwise harming the integrity of the cake.

In some embodiments, recommendations regarding optimized/appropriate locations for the cargo items can be presented via a user's smartphone, an augmented reality (AR)/virtual reality (VR) headset or similar device (e.g., glasses), a heads up display (HUD) of the vehicle, etc. In some embodiments, aspect of AR/VR may be implemented in conjunction with other displays/devices. For example, optimal placement of an item of cargo may be presented via AR elements on a smartphone display. That is, an outline of the item of cargo may be displayed on the smartphone display as the camera of the smartphone simultaneously presents a real-time view of the cargo area in which the item of cargo is to be stored or disposed, at the optimal location, and in its optimal orientation. As another example, optimal location/placement of one or more cargo items may be displayed virtually via a HUD implemented on one or more windows or windshields or components capable of presenting such visualizations. That is, optimal placement of cargo items in a rear trunk of a vehicle may be presented on a HUD implemented on/as part of the rear windshield, whereas optimal placement of cargo items in a front passenger/driver area of the cabin may be presented on a side window or via a user's smartphone. Different visualization methods or mechanisms can, in some embodiments, be used in conjunction with one another depending on, e.g., convenience, availability of a display, proximity to the cargo area(s) of interest, etc. Other methods or mechanisms for presenting such recommendations or instructions for appropriate or optimal placement of cargo items may be used.

In the example shown in FIG. 3A, autonomous control system 200 is provided with an external sensor 201, a GPS (Global Positioning System) reception unit 202, an internal sensor 203, a map database 204, a navigation system 205, actuators 206, an HMI (Human Machine Interface) 207, a monitor device 208, a shift lever 209, auxiliary devices 210. Autonomous control system 200 may communicate with ECU 50, or in some embodiments (may be implemented with its own ECU).

In the example shown in FIG. 3, external sensor 201 is a detector that detects external circumstances such as conditions (e.g., weather, road, traffic, etc.) surrounding or relevant to vehicle 10. For example, based on a calculated navigation route to a particular destination, the existence of traffic may influence cargo storage as traffic typically results in a slower vehicle speeds, which can impact movement or shifting of cargo items, e.g., less likely the move or shift. The external sensor 201 may include at least one of a camera, a radar, and a Laser Imaging Detection and Ranging (LIDAR) unit.

The camera unit may be an imaging device that images the external circumstances surrounding the vehicle. For example, the camera is provided on a back side of a front windshield of the vehicle. The camera may be a monocular camera or a stereo camera. The camera outputs, to the ECU 50, image information on the external circumstances surrounding the vehicle. The camera is not limited to a visible light wavelength camera but can be an infrared camera.

The radar unit uses radio waves to detect obstacles outside of the vehicle by transmitting radio waves to the surroundings of the vehicle, and receiving reflected radio waves from an obstacle to detect the obstacle, distance to the obstacle or a relative positional direction of the obstacle. The radar unit outputs detected obstacle information to the ECU 50.

The LIDAR unit may operate similar to the manner in which the radar unit operates except that light is used in place of radio waves. The LIDAR unit outputs detected obstacle information to the ECU 50.

In the example shown in FIG. 3A, GPS reception unit 202 receives signals from one or more GPS satellites to obtain position information indicating a position of vehicle 10. For example, the position information can include latitude information and longitude information. The GPS reception unit 202 outputs the measured position information of the vehicle to the ECU 50, knowledge of which may impact cargo item placement or orientation in a cargo area of vehicle 10. Again, road surfaces, traffic, environmental conditions relevant to a particular vehicle may be determined in part, based on the measured position of vehicle 10. That is, relevant environmental or road conditions may be determined for a part(s) of the calculated navigation route to be traversed by vehicle 10.

In the example shown in FIG. 3A, the internal sensor 203 is a detector for detecting information regarding, e.g., a running status of vehicle 10, operational/operating conditions that are indicative/representative of vehicle dynamics, e.g., amount of steering wheel actuation, rotation, angle, amount of acceleration, accelerator pedal depression, brake operation by the driver of vehicle 10. The internal sensor 203 includes at least one of a vehicle speed sensor, an acceleration sensor, and a yaw rate sensor. Moreover, internal sensor 203 may include at least one of a steering sensor, an accelerator pedal sensor, and a brake pedal sensor. Internal sensor 203 may also be a camera or other sensor/device sensing activity within vehicle 10.

A vehicle speed sensor is a detector that detects a speed of the vehicle 10. In some embodiments, vehicle 10's speed may be measured directly or through calculations/inference depending on the operating conditions/status of one or more other components of vehicle 10. For example, a wheel speed sensor can be used as the vehicle speed sensor to detect a rotational speed of the wheel, which can be outputted to ECU 50.

The acceleration sensor can be a detector that detects an acceleration of the vehicle. For example, the acceleration sensor may include a longitudinal acceleration sensor for detecting a longitudinal acceleration of vehicle 10, and a lateral acceleration sensor for detecting a lateral acceleration of vehicle 10. The acceleration sensor outputs, to the ECU 50, acceleration information.

The yaw rate sensor can be a detector that detects a yaw rate (rotation angular velocity) around a vertical axis passing through the center of gravity of vehicle 10. For example, a gyroscopic sensor is used as the yaw rate sensor. The yaw rate sensor outputs, to the ECU 50, yaw rate information including the yaw rate of vehicle 10.

The steering sensor may be a detector that detects an amount of a steering operation/actuation with respect to a steering wheel 30 by the driver of vehicle 10. The steering operation amount detected by the steering sensor may be a steering angle of the steering wheel or a steering torque applied to the steering wheel, for example. The steering sensor outputs, to the ECU 50, information including the steering angle of the steering wheel or the steering torque applied to the steering wheel of vehicle 10.

The accelerator pedal sensor may be a detector that detects a stroke amount of an accelerator pedal, for example, a pedal position of the accelerator pedal with respect to a reference position. The reference position may be a fixed position or a variable position depending on a determined parameter. The accelerator pedal sensor is provided to a shaft portion of the accelerator pedal AP of the vehicle, for example. The accelerator pedal sensor outputs, to the ECU 50, operation information reflecting the stroke amount of the accelerator pedal.

The brake pedal sensor may be a detector that detects a stroke amount of a brake pedal, for example, a pedal position of the brake pedal with respect to a reference position. Like the accelerator position, a brake pedal reference position may be a fixed position or a variable position depending on a determined parameter. The brake pedal sensor may detect an operation force of the brake pedal (e.g. force on the brake pedal, oil pressure of a master cylinder, and so on). The brake pedal sensor outputs, to the ECU 50, operation information reflecting the stroke amount or the operation force of the brake pedal.

A map database 204 may be a database including map information. The map database 204 is implemented, for example, in a disk drive or other memory installed in vehicle 10. The map information may include road position information, road shape information, intersection position information, and fork position information, for example. The road shape information may include information regarding a road type such as a curve and a straight line, and a curvature angle of the curve. When autonomous control system 200 uses a Simultaneous Localization and Mapping (SLAM) technology or position information of blocking structural objects such as buildings and walls, the map information may further include an output signal from external sensor 201. In some embodiments, map database 204 may be a remote data base or repository with which vehicle 10 communicates.

Navigation system 205 may be a component or series of interoperating components that guides the driver of vehicle 10 to a destination on a map designated by the driver of vehicle 10. For example, navigation system 205 may calculate a route followed or to be followed by vehicle 10, based on the position information of vehicle 10 measured by GPS reception unit 202 and map information of map database 204. The route may indicate a running lane of a section(s) of roadway in which vehicle 10 traverses, for example. Navigation system 205 calculates a target route from the current position of vehicle 10 to the destination, and notifies the driver of the target route through a display, e.g., a display of a head unit, HMI 207 (described below), and/or via audio through a speaker(s) for example. The navigation system 205 outputs, to the ECU 50, information of the target route for vehicle 10. In some embodiments, navigation system 205 may use information stored in a remote database, like map database 204, and/or some information processing center with which vehicle 10 can communicate. A part of the processing executed by the navigation system 205 may be executed remotely as well.

Actuators 206 may be devices that execute running controls of vehicle 10. The actuators 206 may include, for example, a throttle actuator, a brake actuator, and a steering actuator. For example, the throttle actuator controls, in accordance with a control signal output from the ECU 50, an amount by which to open the throttle of vehicle 10 to control a driving force (the engine) of vehicle 10. In another example, actuators 206 may include one or more of MGs 91 and 92, where a control signal is supplied from the ECU 50 to MGs 91 and/or 92 to output motive force/energy. The brake actuator controls, in accordance with a control signal output from the ECU 50, the amount of braking force to be applied to each wheel of the vehicle, for example, by a hydraulic brake system. The steering actuator controls, in accordance with a control signal output from the ECU 50, driving an assist motor of an electric power steering system that controls steering torque.

HMI 207 may be an interface used for communicating information between a passenger(s) (including the operator) of vehicle 10 and autonomous control system 200. For example, the HMI 207 may include a display panel for displaying image information for the passenger(s), a speaker for outputting audio information, and operation buttons or a touch panel used by the occupant for performing an input operation. HMI 207 may also or alternatively transmit the information to the passenger(s) through a mobile information terminal connected wirelessly and receive the input operation by the passenger(s) through the mobile information terminal. As noted above, HMI 207 may be embodied by or as a HUD, a user's smartphone or other portable computing device (tablet, laptop), AR/VR device, etc.

ECU 50 may execute control of the vehicle, and may include an acquisition unit 211, a recognition unit 212, a navigation plan generation unit 213, a calculation unit 214, a control unit 216, a memory unit 218, and a communications unit 219.

Acquisition unit 211 may obtain the following operation amounts or levels of actuation based on the information obtained by the internal sensor 203: steering operation, acceleration operation, and brake operation by the driver during an autonomous control mode; and the level of steering operation, acceleration operation, and brake operation by the driver of the vehicle during a manual control mode.

Recognition unit 212 may recognize or assess the environment surrounding or neighboring vehicle(s) based on the information obtained by the external sensor 201, the GPS reception unit 202, and/or the map database 204. For example, the recognition unit 212 includes an object or obstacle recognition unit (not shown), a road width recognition unit (not shown), and a facility recognition unit (not shown). The obstacle recognition unit recognizes, based on the information obtained by the external sensor 201, obstacles surrounding the vehicle. For example, the obstacles recognized by the obstacle recognition unit include moving objects such as pedestrians, other vehicles, motorcycles, and bicycles and stationary objects such as a road lane boundary (white line, yellow line), a curb, a guard rail, poles, a median strip, buildings and trees. The obstacle recognition unit obtains information regarding a distance between the obstacle and the vehicle, a position of the obstacle, a direction, a relative velocity, a relative acceleration of the obstacle with respect to the vehicle, and a category and attribution of the obstacle. The category of the obstacle includes a pedestrian, another vehicle, a moving object, and a stationary object. The attribution of the obstacle can refer to a property of the obstacle such as hardness and a shape of the obstacle. Such information can impact vehicle or driving dynamics, which can impact the manner in which stowed cargo “reacts” (moves/shifts).

The road width recognition unit recognizes, based on the information obtained by the external sensor 201, the GPS reception unit 202, and/or the map database 204, a road width of a road in which the vehicle is running.

The facility recognition unit recognizes, based on the map information obtained from the map database 204 and/or the vehicle position information obtained by the GPS reception unit 202, whether or not vehicle 10 is operating/being driven through an intersection, in a parking structure, etc. The facility recognition unit may recognize, based on the map information and the vehicle position information, whether or not the vehicle is running in a school zone, near a childcare facility, near a school, or near a park, etc.

Moreover, recognition unit 212 may include a cargo recognition component (not shown) for determining what cargo is to be stowed or stored, in this example, in one or more cargo areas of vehicle 10. In some embodiments, cargo recognition component may comprise a camera(s) capable of capturing cargo placed in/on cargo areas of vehicle 10. In some embodiments, cargo recognition component may comprise pressure sensors or similar sensors for detecting presence, weight, or other characteristics of cargo. In some embodiments HMI 207 may include input mechanisms allowing a user to input information regarding cargo to be stowed in vehicle 10. The type or amount of information that can be entered may vary. A user may input all relevant cargo item information to be used by recognition unit 212. In other embodiments, a user may input some relevant cargo item information to be used by recognition unit 212. It should be understood that recognition unit 212 may attempt to ascertain other relevant cargo item characteristics information as may be needed to provide optimized cargo information/recommendations described herein. In other embodiments, optimized cargo placement/location information may be provided on a “best-available” basis, e.g., the best optimized placement/location recommendation may be provided based on whatever driving dynamics and cargo characteristics information is available at the time the recommendation is requested or is to be set forth.

Navigation plan generation unit 213 may generate a navigation plan for vehicle 10 based on the target route calculated by the navigation system 205, the information on obstacles surrounding vehicle 10 recognized by recognition unit 212, and/or the map information obtained from map database 204. The navigation plan may be reflect one or more operating conditions/controls to effectuate the target route. For example, the navigation plan can include a target speed, a target acceleration, a target deceleration, a target direction, and/or a target steering angle with which vehicle 10 should be operated at any point(s) along the target route so that the target route can be achieved to reach a desired destination. It should be understood that navigation plan generation unit 213 generates the navigation plan such that vehicle 10 operates along the target route while satisfying one or more criteria and/or constraints, including, for example, safety constraints, legal compliance rules, operating (fuel/energy) efficiency, and the like. Moreover, based on the existence of obstacles surrounding vehicle 10, the navigation plan generation unit 213 generates the navigation plan for the vehicle so as to avoid contact with such obstacles. In some embodiments, avoidance of such obstacles may impact resultant movement or shifting of a cargo item, or, in some embodiments, may reflect driving dynamics or behaviors that impact cargo items during transit in vehicle 10.

Control unit 216 can control vehicle 10 based on the navigation plan generated by navigation plan generation unit 213. The control unit 216 outputs, to the actuators 206, control signals according to the navigation plan.

In some embodiments, at least some components or operations described herein used to optimize cargo item placement or orientation in accordance with various embodiments may be performed on-vehicle, or off-vehicle. Regarding off-vehicle cargo optimization, a cloud or edge server 220 may perform the requisite calculations/processing to determine where an item of cargo should be stowed. It should be understood that different vehicles may have different processing capabilities. Additionally, as described above, certain embodiments may be used to optimize cargo placement in a fleet vehicle (or similar) context, where cargo optimization may be performed for/applied to a plurality of vehicles. Accordingly, distribution of cargo optimization information/presentations may be advantageous to effectuate using a remote centralized or distributed system (such as that made possible through the use of one or more cloud/edge server(s) 220 (as opposed to on-vehicle systems). In some embodiments, ECU 50 may communicate with cloud/edge server 220 via a communications unit 219, which may comprise a transceiver or other known communications elements for effectuating wireless/remote communications.

Calculation unit 214, described in greater detail below, may calculate or otherwise determine an optimal location/placement/orientation of an item of cargo to be stored. That is, in some embodiments, calculation unit 214 may be an embodiment of the above-noted recommendation engine or a component in which the above-noted recommendation engine may be implemented. In some embodiments, calculation unit 214 receives information (current or historical) regarding factors or conditions relevant to determining optimized cargo item placement/orientation/arrangement. As described above, such information can be information gleaned from one or more sensors (pitch, yaw, roll), from third-party information sources (traffic/weather information source), as well as driving behavior(s) associated with the vehicle or driver, or characteristics of the cargo area(s) to be used. Other information relevant to determining optimized cargo item placement/orientation/arrangement may include characteristics of the cargo items to be stowed. Based on this information, calculation unit 214 may determine optimal or appropriate cargo item placement in the cargo area(s).

In some embodiments, each cargo area of a vehicle (or other entity, area where cargo may be stored) may be associated with items that may be stored in that respective cargo area. For example, a center console tray below the head unit, e.g., a front portion 22F of center console 22 (FIG. 1) may be represented in a listing, table, or other data store/set. Associated with the front portion 22F may be one or more cargo items that are allowed to be stored therein/thereon. For example, items whose size/shape fall within a threshold size/shape associated with the front portion 22F may be reasonably stored therein. In some embodiments, calculation unit 214 may calculate an appropriate orientation or position relative to other items to be stored therein. The items that may be stored therein may further be associated (in the data store) with maximum speeds or vehicle operating conditions. That is, in addition to size/shape, the driving dynamics of a vehicle also play a role in determining whether or not an item(s) may be stored in a particular cargo area.

As noted above, a recommendation engine may comprise a driver behavior determination component, a vehicle dynamics determination component, a cargo characteristics component, and a prediction or recommendation. In some embodiments, a model(s) may be generated for simulating (and later predicting) the effect of the motion of the car on an item. In some embodiments, as illustrated in FIG. 3B, cargo characteristics component 214a may comprise a first (item movement) model 214a-1 that may be developed for simulating the motion of an item in response to an external force(s), and driving/vehicle characteristics component 214b may comprise a second (vehicle dynamics/movement) model 214b-1 for simulating the motion of a vehicle, (and how the (overall) motion of the vehicle translates to (specific/particular) motion(s) at every single point/relevant point within the vehicle may be developed. In some embodiments, and with proper training, vis-à-vis training data/corpus or training data sets, a combined model capable of simulating both vehicle and item motion in a vehicle may be utilized. It should be understood that in some embodiments, the driving/vehicle characteristics, cargo characteristics, etc. gleaned from the in/on-vehicle sensors and mechanisms can be collected and used as training data for the disclosed models in addition to being “direct” input for such models.

For example, consider a scenario in which a user wishes to pack two boxes and a bag in a vehicle. The physical characteristics of each item (the two boxes and the bag in this example) are collected and entered into the first (item motion simulation) model. The physical characteristics can vary as appropriate to an item, but as an example, such physical characteristics can include, but are not necessarily limited to one or more of (size, weight, weight distribution within an item, fragility, shape, etc.

Using the second model (for vehicle motion simulation/prediction), the motion of a vehicle can be simulated/predicted with respect to, e.g., known scenarios (highway driving with high speeds and no stops, urban driving with low average speed and frequent stops, driving along a route with frequent turns, and so on). It should be understood that there may be more (or less) scenarios in which to simulate/predict vehicle motion. For example, when considering packaging a sedan versus a sport utility vehicle or two-seat sports car, location, weather, etc., known scenarios may vary.

In each simulated scenario, movement at each location or stage of travel for a vehicle may be assessed (for example, in the case of a sudden stop, the vehicle's rear section will experience a larger change in displacement or a larger change in momentum compared to the vehicle's front section). Similarly, a “location” near the roof of a vehicle may experience a higher change in momentum compared to the floor of the car. In this way, the manner in which a vehicle reacts to conditions (roadway or otherwise), weather, and so on, can be determined and applied to an item.

Likewise, and in some embodiments, in parallel, a simulation/prediction model can be applied to each item based at least on the above-noted physical characteristics of the item to be packed/stored in a vehicle. That is, execution of the simulation/prediction model (using the item physical characteristics input, discussed above), a determination(s) can be made regarding how an item of a particular size, weight, weight distribution, shape, etc. responds to external force(s)/movement(s), such as vehicle movement. As one example, if the “external” movement of a vehicle changes from 30 mph to 0 mph in a few seconds (simulating braking in an urban setting), the simulation/predication model can determine how much force such an action/movement places on the item or different parts of the item (given its rigidity, size, and weight distribution, etc.).

Once the impact of a vehicle's motion on an item is determined, the first and second models can be “combined” to simulate and predict the effect of movement on an item in various points/areas/locations within the vehicle (or anywhere an item(s) may be placed, e.g., external roof rack). In some instances, this combined model 214c-1 may embody the aforementioned prediction or recommendation component 214c. In some embodiments, combining the models may involve obtaining a result(s)/output(s) from each of the models and analyzing them together to predict the effects of movement at certain areas. In some embodiments, a new model, which combines the first and second models may be generated, either serially or in parallel. When combining the first and second models in a serial or sequential fashion, the output of the one model can be used as input to the other model. The use of this combined model can be an iterative process. When combining models in a parallel fashion, motion due to multiple forces can be simulated, as can motion (of items) at multiple speed until the motion prediction of the two models converge The resulting predictions provide information that can be the basis for where items should be placed, e.g., in the front of the vehicle, bottom of the passenger seat, at the very back of the cargo area, etc. That is, upon determining the impact certain vehicle movements have on certain items, a packing strategy or plan can be developed (via further simulation using the combined model) that negates, mitigates, or otherwise counters any negative or undesirable movements/actions imparted on the item. That is, the combined model (or other AI-driven software/algorithm(s) can compare the prediction results (where an item will experience unwanted motion) and negate areas where that unwanted motion is predicted to occur, until one or more areas/locations remain where the item is predicted to remain motionless or will experience acceptable/allowed amount(s) of movement.

In order to determine how the items should be placed or positioned in relation to one another in the case of multiple items being stored in proximity or in contact with at least one other item, another simulation can be performed with the combined model, where the items are in their respective “recommended” places, and item-related interaction information is input into the combined model. Such information can include, but is not limited to respective coefficients of friction associated with item surfaces, point(s) of contact between items given the respective shapes of the items, or other relevant item-related interaction information. As an example of how such item-related interaction information may be relevant to determine packing, when a first box is placed atop a second box, their aggregate coefficient of friction will differ from what was inputted in the first, “individual-item” model. By considering such interactions, the simulation/prediction model can ensure that the interaction between the items do not introduce an additional external force (for example, the first box sliding over, falling off the second box, and subsequently falling on the bag).

In some embodiments, an algorithm(s) may be used to predict what/in what way, one or more cargo items may be stored, and how they may be stored in a particular cargo area. That is, calculation unit 214 may comprise a prediction algorithm or model, as discussed above, to determine what/how cargo items are to be stored in a particular cargo area. In some embodiments, a machine learning predictive algorithm may be developed and used to make such determinations, such as regression algorithms, learning vector quantization algorithms, etc. In some embodiments, the prediction algorithm or model may predict, not only how cargo items may be optimally or appropriately organized within a particular cargo area(s), but may determine which cargo area(s) may be appropriate for stowing particular cargo items. Such algorithms or models may be trained using data sets involving various cargo items and vehicles, for example, along with related driving behavior/vehicle dynamics information.

In some embodiments, calculation unit 214 may determine an optimal or appropriate location/orientation of each cargo item to be stored relative to a cargo area(s) and other cargo items to be stored therein. Upon determining optimal placement/location(s) for each cargo item, calculation unit 214 may then calculate an overall optimal or appropriate location/placement of all the cargo items. In some embodiments, calculation unit 214 may comprise a plurality of cargo optimization algorithms or models, where certain cargo optimization algorithms or models may be used in association with particular cargo areas or types of cargo items. Depending on the circumstances, i.e., what cargo is being stored or where, an appropriate algorithm or model can be selected and used to output a recommended cargo layout indicating optimal or appropriate cargo item location and placement. In still other embodiments, driving dynamics information, cargo area information, cargo item information, or driving behavior information may be input into a variety of cargo optimization algorithms and models. Each of the cargo optimization algorithms and models may output a cargo optimization recommendation, such as a recommended cargo layout. Each recommendation may then be compared to data reflecting historical or know cargo layouts or recommendations such that the cargo optimization recommendation having the least or some minimum threshold amount or level or error may be determined to be the final or possible cargo optimization recommendation. As also noted above, a reverse-iterative methodology may be used to weed out or negate those instances of item movement in particular areas that produce an undesirable result.

It should be understood that the above-noted algorithms or models may be configured or designed as desired, e.g., to accommodate different types of vehicles, sizes of vehicles, types of cargo areas, scenarios in which vehicles may operate. In some embodiments, failed or successful simulations can be used as feedback for the simulation/prediction models. For example, in one simulation, a box placed atop results in a sensor sensing movement of the box. Accordingly, a simulation/prediction model used for or applied to seat storage may be updated to predict undesirable results, e.g., movement, when a box is placed atop a seat. In some embodiments, a scoring aspect may be implemented, the scoring aspect being based on common or known items for which simulations have been previously performed. For example, historical results of simulations/predictions may be maintained in a cache or memory, e.g., memory unit 218. In this way, in some embodiments, predictions can be generated more quickly by not having to run full/entire simulations. Rather, when a score, prediction, or other data associated with a known item or a known item in a vehicle movement scenario is encountered, such data can be retrieved and used as a prediction.

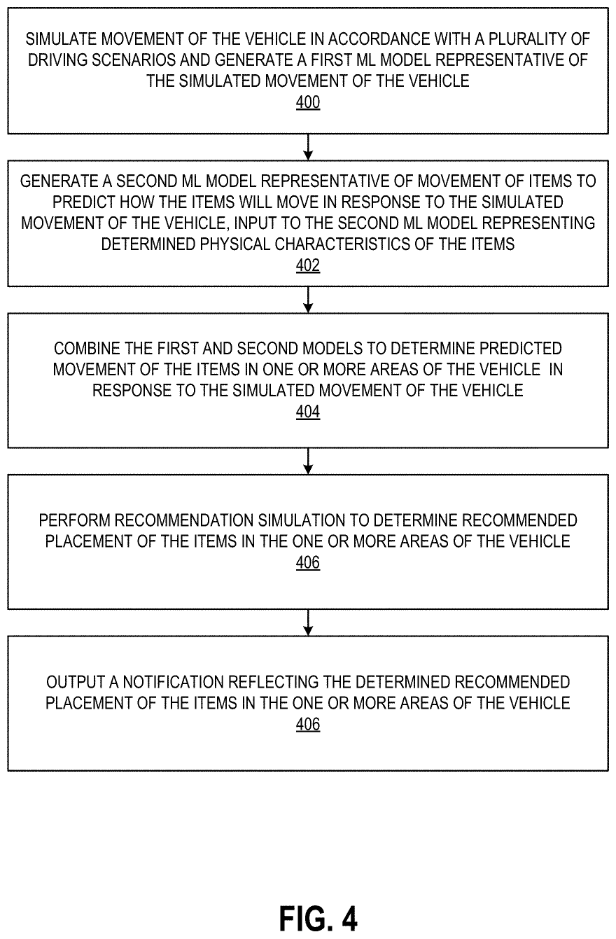

FIG. 4 is a flow chart illustrating example operations that can be performed to produce an optimized cargo recommendation in accordance with one embodiment. In some embodiments, as described above, at operation 400, movement of a vehicle is simulated in accordance with a plurality of driving scenarios. A machine learning model representative of the simulated movement of the vehicle may be generated. In this way, when a vehicle motion simulation is performed, the machine learning model is able to predict how a vehicle will react to different driving/road/environmental scenarios.

At operation 402, a second machine learning model representative of the movement of items may be generated to predict how items will move in response to the simulated movement of the vehicle. As noted above, inputs to the send model may include determined physical characteristics of the items.

At operation 404, the first and second models may be combined to determine the predicted movement of the items in one or more areas of the vehicle in response to simulated movement of the vehicle. As described above, combining the first and second models may entail combining the logic/algorithms representative of each of the first and second models and training them/executing them as a single, combined model. In other embodiments, the output of one model may be used as input to the other model, or the first and second models may be run in parallel until convergence.

At operation 406, a recommendation simulation may be performed to determine recommended placement of the items in the one or more areas of the vehicle. As discussed above, in order to determine how the items should be placed or positioned in relation to one another, another simulation can be performed, where the items are in their respective “recommended” places, and item-related interaction information is input into the combined model. In other embodiments, rather than performing another simulation, areas/items that result in undesirable movement of the item can be negated from consideration until areas/items that result in desirable movement (or lack of movement) remain. These remaining combinations of items/areas where those items may be placed can be the basis for a placement recommendation.

At operation 408, a notification reflecting the determined recommended placement of the items in the one or more areas of the vehicle may be output. In some embodiments, a notification may take the form of textual recommendations, visual recommendations, etc. For example, such a notification may be presented on a display unit (head unit) of the vehicle. In some embodiments, the notification may be communicated to a user's mobile device via communications unit 219 (FIG. 3A). In still other embodiments, a heads up display of a vehicle may be used to display or present the notification. In some embodiments, the heads up display may be implemented on a window/windshield proximate to or providing a view into the vehicle's cargo area(s).

As used herein, the terms circuit and component might describe a given unit of functionality that can be performed in accordance with one or more embodiments of the present application. As used herein, a component might be implemented utilizing any form of hardware, software, or a combination thereof. For example, one or more processors, controllers, ASICs, PLAs, PALs, CPLDs, FPGAs, logical components, software routines or other mechanisms might be implemented to make up a component. Various components described herein may be implemented as discrete components or described functions and features can be shared in part or in total among one or more components. In other words, as would be apparent to one of ordinary skill in the art after reading this description, the various features and functionality described herein may be implemented in any given application. They can be implemented in one or more separate or shared components in various combinations and permutations. Although various features or functional elements may be individually described or claimed as separate components, it should be understood that these features/functionality can be shared among one or more common software and hardware elements. Such a description shall not require or imply that separate hardware or software components are used to implement such features or functionality.

Where components are implemented in whole or in part using software, these software elements can be implemented to operate with a computing or processing component capable of carrying out the functionality described with respect thereto. One such example computing component is shown in FIG. 6. Various embodiments are described in terms of this example-computing component 600. After reading this description, it will become apparent to a person skilled in the relevant art how to implement the application using other computing components or architectures.

Referring now to FIG. 6, computing component 600 may represent, for example, computing or processing capabilities found within a self-adjusting display, desktop, laptop, notebook, and tablet computers. They may be found in hand-held computing devices (tablets, PDA's, smart phones, cell phones, palmtops, etc.). They may be found in workstations or other devices with displays, servers, or any other type of special-purpose or general-purpose computing devices as may be desirable or appropriate for a given application or environment. Computing component 600 might also represent computing capabilities embedded within or otherwise available to a given device. For example, a computing component might be found in other electronic devices such as, for example, portable computing devices, and other electronic devices that might include some form of processing capability.

Computing component 600 might include, for example, one or more processors, controllers, control components, or other processing devices. This can include a processor 604. Processor 604 might be implemented using a general-purpose or special-purpose processing engine such as, for example, a microprocessor, controller, or other control logic. Processor 604 may be connected to a bus 602. However, any communication medium can be used to facilitate interaction with other components of computing component 600 or to communicate externally.

Computing component 600 might also include one or more memory components, simply referred to herein as main memory 608. For example, random access memory (RAM) or other dynamic memory, might be used for storing information and instructions to be executed by processor 604. Main memory 608 might also be used for storing temporary variables or other intermediate information during execution of instructions to be executed by processor 604. Computing component 600 might likewise include a read only memory (“ROM”) or other static storage device coupled to bus 602 for storing static information and instructions for processor 604.

The computing component 600 might also include one or more various forms of information storage mechanism 610, which might include, for example, a media drive 612 and a storage unit interface 620. The media drive 612 might include a drive or other mechanism to support fixed or removable storage media 614. For example, a hard disk drive, a solid-state drive, a magnetic tape drive, an optical drive, a compact disc (CD) or digital video disc (DVD) drive (R or RW), or other removable or fixed media drive might be provided. Storage media 614 might include, for example, a hard disk, an integrated circuit assembly, magnetic tape, cartridge, optical disk, a CD or DVD. Storage media 614 may be any other fixed or removable medium that is read by, written to or accessed by media drive 612. As these examples illustrate, the storage media 614 can include a computer usable storage medium having stored therein computer software or data.

In alternative embodiments, information storage mechanism 610 might include other similar instrumentalities for allowing computer programs or other instructions or data to be loaded into computing component 600. Such instrumentalities might include, for example, a fixed or removable storage unit 622 and an interface 620. Examples of such storage units 622 and interfaces 620 can include a program cartridge and cartridge interface, a removable memory (for example, a flash memory or other removable memory component) and memory slot. Other examples may include a PCMCIA slot and card, and other fixed or removable storage units 622 and interfaces 620 that allow software and data to be transferred from storage unit 622 to computing component 600.

Computing component 600 might also include a communications interface 624. Communications interface 624 might be used to allow software and data to be transferred between computing component 600 and external devices. Examples of communications interface 624 might include a modem or softmodem, a network interface (such as Ethernet, network interface card, IEEE 802.XX or other interface). Other examples include a communications port (such as for example, a USB port, IR port, RS232 port Bluetooth® interface, or other port), or other communications interface. Software/data transferred via communications interface 624 may be carried on signals, which can be electronic, electromagnetic (which includes optical) or other signals capable of being exchanged by a given communications interface 624. These signals might be provided to communications interface 624 via a channel 628. Channel 628 might carry signals and might be implemented using a wired or wireless communication medium. Some examples of a channel might include a phone line, a cellular link, an RF link, an optical link, a network interface, a local or wide area network, and other wired or wireless communications channels.

In this document, the terms “computer program medium” and “computer usable medium” are used to generally refer to transitory or non-transitory media. Such media may be, e.g., memory 608, storage unit 620, media 614, and channel 628. These and other various forms of computer program media or computer usable media may be involved in carrying one or more sequences of one or more instructions to a processing device for execution. Such instructions embodied on the medium, are generally referred to as “computer program code” or a “computer program product” (which may be grouped in the form of computer programs or other groupings). When executed, such instructions might enable the computing component 600 to perform features or functions of the present application as discussed herein.

It should be understood that the various features, aspects and functionality described in one or more of the individual embodiments are not limited in their applicability to the particular embodiment with which they are described. Instead, they can be applied, alone or in various combinations, to one or more other embodiments, whether or not such embodiments are described and whether or not such features are presented as being a part of a described embodiment. Thus, the breadth and scope of the present application should not be limited by any of the above-described exemplary embodiments.

Terms and phrases used in this document, and variations thereof, unless otherwise expressly stated, should be construed as open ended as opposed to limiting. As examples of the foregoing, the term “including” should be read as meaning “including, without limitation” or the like. The term “example” is used to provide exemplary instances of the item in discussion, not an exhaustive or limiting list thereof. The terms “a” or “an” should be read as meaning “at least one,” “one or more” or the like; and adjectives such as “conventional,” “traditional,” “normal,” “standard,” “known.” Terms of similar meaning should not be construed as limiting the item described to a given time period or to an item available as of a given time. Instead, they should be read to encompass conventional, traditional, normal, or standard technologies that may be available or known now or at any time in the future. Where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the term “component” does not imply that the aspects or functionality described or claimed as part of the component are all configured in a common package. Indeed, any or all of the various aspects of a component, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

What is claimed is:

1. A system, comprising:
a processor; and
a memory unit operatively connected to the processor and including instructions that when executed cause the processor to:
simulate movement of a vehicle in accordance with a driving scenario and generate a first model representative of the simulated movement of the vehicle;
generate a second model representative of movement of an item to predict how the item will move in response to the simulated movement of the vehicle, wherein input to the second model represents physical characteristics of the item;
combine the first and second models to determine predicted movement of the item in one or more areas of the vehicle in response to the simulated movement of the vehicle;
perform a recommendation simulation to determined recommended placement of the item in the one or more areas of the vehicle; and
output a notification reflecting the determined recommended placement of the item in the one or more areas of the vehicle.

2. The system of claim 1, wherein the memory unit includes instructions that when executed further cause the processor to determine an experienced change in displacement or change in momentum at the one or more areas of the vehicle in response to the simulated movement of the vehicle.

3. The system of claim 2, wherein the instructions that when executed cause the processor to combine the first and second models further cause the processor to determine predicted movement of the item at the one or more areas of the vehicle.

4. The system of claim 3, wherein the instructions that when executed cause the processor to combine the first and second models further cause the processor to generate a sequentially combined model.

5. The system of claim 4, wherein the instructions that when executed cause the processor to generate a sequentially combined model further cause the processor to use the output of the first model as an input to the second model, and executing the second model.

6. The system of claim 4, wherein the instructions that when executed cause the processor to generate a parallel combined model.

7. The system of claim 6, wherein the instructions that when executed cause the processor to generate a parallel combined model further cause the processor to execute the first and second models in parallel until convergence with the first and second models is achieved.

8. The system of claim 3, wherein the instructions that when executed cause the processor to perform the recommendation simulation comprises negating predicted movement of the item at the one or more areas of the vehicle that are undesirable.

9. The system of claim 1, wherein the memory unit includes further instructions that when executed cause the processor to determine predicted item interactions based on item-related interaction information input into the combination of the first and second models at the one or more areas of the vehicle.

10. A system, comprising:
a processor; and
a memory unit operatively connected to the processor and including instructions that when executed cause the processor to:
predict movement of an item in response to a plurality of external forces applied to the item, the plurality of external forces comprising movement of a vehicle in which the item is stored;
predict movement of the vehicle in response to a plurality of driving scenarios;
predict the movement of the item in particular locations of the vehicle relative to each of the plurality of driving scenarios based on a prediction generated by one or more models incorporating the predicted movement of the item responsive to the plurality of external forces and the predicted movement of the vehicle responsive to the plurality of driving scenarios; and
determine whether the movement of the item in each of the particular locations is commensurate with a desired storage location for the item; and
upon determining that the movement of the item in one or more of the particular locations is commensurate with a desired storage location, output a recommendation regarding placement of the item in the vehicle in accordance with the desired storage location for the item.

11. The system of claim 10, wherein the movement of the item is predicted by a first machine learning model considering physical characteristics of the item.

12. The system of claim 10, wherein the movement of the vehicle is predicted by a second machine learning model considering at least one of driving characteristics of a user operating the vehicle, external conditions, and vehicle dynamics associated with the vehicle.

13. The system of claim 12, wherein the movement of the item in the particular locations of the vehicle is predicted by a combination of the first and second machine learning models.

14. The system of claim 13, wherein the combination of the first and second machine learning models comprises a sequentially combined machine learning model.

15. The system of claim 14, wherein the memory unit includes further instructions that when executed cause the processor to use the predicted movement of the item determined by the first machine learning model as input to the second machine learning model and executing the second machine learning model.

16. The system of claim 13, wherein the combination of the first and second machine learning models comprises a parallel combined machine learning model.

17. The system of claim 16, wherein the memory unit includes further instructions that when executed cause the processor to execute the first and second machine learning models until convergence is achieved.

18. The system of claim 13, wherein the memory unit includes further instructions that when executed cause the processor to determine predicted item interactions based on item-related interaction information input into the combination of the first and second machine learning models.

19. The system of claim 10, wherein the memory unit includes further instructions that when executed cause the processor determine one or more of the particular locations of the vehicle at which the predicted movement of the item is undesirable.

20. The system of claim 19, wherein the instructions that when executed cause the processor to output the recommendation regarding placement of the item further cause the processor to exclude the determined one or more of the particular locations of the vehicle at which the predicted movement of the item is undesirable.
